(19) United States
(12) Patent Application Publication
(10) Pub. No.: US 2018/0356661 A1
(43) Pub. Date: Dec. 13, 2018

(54) DISPLAY DEVICE

(71) Applicant: LG Display, Co., Ltd., Seoul (KR)

(72) Inventor: Sungkwon LEE, Paju-si (KR)

(21) Appl. No.: 16/000,346

(22) Filed: Jun. 5, 2018

(30) Foreign Application Priority Data
Jun. 9, 2017 (KR) 10-2017-0072735

(51) Int. Cl. G02F 1/1368; G02F 1/1335; H01L 27/12; G02F 1/1362; G09G 3/36; G02F 1/1333; G02F 1/133

(52) U.S. Cl. CPC G02F 1/1368; G02F 1/133514; H01L 27/124; G02F 1/136286; G02F 2201/123; G02F 1/133345; G02F 1/13318; G02F 2201/121; G09G 3/3688

(57) ABSTRACT

A display device including an optical module such as a camera and an optical sensor is disclosed. The display device includes a display panel including a first substrate and a second substrate that are positioned opposite each other, and an optical module introduced into an open hole penetrating at least a portion of the first substrate. The display panel includes a sensing metal that is disposed on the first substrate and is positioned adjacent to the open hole. The sensing metal is directly disposed on the first substrate and has a planar shape of a closed curve.

### CROSS-REFERENCE TO RELATED APPLICATION(S)

This application claims the priority benefit of Korean Patent Application No. 10-2017-0072735, filed Jun. 9, 2017, which is incorporated herein by reference for all purposes as if fully set forth herein.

### BACKGROUND

### Technical Field

The present disclosure relates to a display device including an optical module such as a camera and/or an optical sensor.

### Description of the Related Art

Various types of display devices have been used to replace heavier and larger cathode ray tubes (CRTs). Examples of the display devices include a liquid crystal display (LCD), a field emission display (FED), a plasma display panel (PDP), and an organic light emitting diode (OLED) display.

Display devices have been applied to various fields including televisions, car displays, wearable devices, etc. as well as mobile terminals such as smart phones and tablet PCs. Various structural modifications are performed to apply these display devices to various fields.

For example, it may be desirable for display devices to have a thinner profile in consideration of portability and usability of users or aesthetics of the product, etc. However, display devices have increasingly more functions in addition to a function of providing image information. The display device has been implemented as a multimedia player having various functions of taking pictures or videos, playing music or video files, playing games, receiving broadcasts, etc. Thus, the display device includes many components for performing the various functions. However, because it is difficult to implement a slim design of the display device through a simple process for stacking the many components, the display device has a limit in securing the desired portability and usability of the users, etc.

### BRIEF SUMMARY

In various embodiments, the present disclosure provides a display device capable of securing portability, usability, and aesthetics even when including an optical module such as a camera and/or an optical sensor.

In one embodiment, there is provided a display device including a display panel including a first substrate having a hole that extends through at least a portion of the first substrate, a second substrate that is positioned opposite to the first substrate, and a sensing metal on a surface of the first substrate that faces the second substrate. The sensing metal is positioned adjacent to the hole in the first substrate. The display panel further includes an optical module at least partially located within the hole of the first substrate.

The sensing metal may be directly disposed on the first substrate.

The sensing metal may be spaced apart from the first substrate by an insulating layer.

The sensing metal may have a planar shape of a closed curve.

The display device may further include a thin film transistor on the first substrate. The thin film transistor includes a gate electrode directly disposed on the first substrate, a gate insulating layer on the gate electrode, a semiconductor layer disposed on the gate insulating layer and at least partially overlapping the gate electrode, and a source electrode and a drain electrode disposed on the semiconductor layer and respectively contacting opposite sides of the semiconductor layer. The sensing metal may be formed on a same layer and of a same material as the gate electrode.

The display panel may include a first area in which the hole is positioned, a second area disposed outside the first area, the second area operable to display an input image, and a barrier disposed between the first substrate and the second substrate and partitioning the first area and the second area.

The sensing metal may be disposed in the first area. The sensing metal may be spaced apart from the barrier.

The display device may further include a liquid crystal layer between the first substrate and the second substrate in the second area.

A planar shape of the open hole and a planar shape of the sensing metal may be the same. The planar shape of the hole and the sensing metal may be a circular or semi-circular shape.

The optical module may include at least one of a camera and an optical sensor.

In another embodiment, the present disclosure provides a method that includes: positioning a mechanical wheel over a first substrate of a display panel, the display panel including a second substrate positioned opposite to the first substrate, and a sensing metal on a surface of the first substrate that faces the second substrate; sensing a distance between a distance sensor and the sensing metal; and drilling a region of the first substrate, by the mechanical wheel, to a selected depth while sensing the distance between the distance sensor and the sensing metal.

In some embodiments, the method may further include determining, based on the sensed distance between the distance sensor and the sensing metal, that the first substrate has been drilled to the selected depth.

In some embodiments, the method may further include removing a portion of the first substrate to form a hole through the first substrate, the hole corresponding to the drilled region of the first substrate.

In some embodiments, the method may further include positioning at least one of a camera and an optical sensor in the hole.

### BRIEF DESCRIPTION OF THE SEVERAL VIEWS OF THE DRAWINGS

The accompanying drawings, which are included to provide a further understanding of the disclosure and are incorporated in and constitute a part of this specification, illustrate embodiments of the disclosure and together with the description serve to explain various principles of the disclosure.

FIG. 1 is a schematic block diagram of a display device according to an embodiment of the disclosure.

FIG. 2 is a cross-sectional view illustrating a schematic structure of a display device according to an embodiment of the disclosure.

FIGS. 3A and 3B are cross-sectional views illustrating a manufacturing process of a display device according to an embodiment of the disclosure.

FIG. 4 is a cross-sectional view illustrating a schematic structure of a display device according to an embodiment of the disclosure.

FIGS. 5A, 5B, and 5C are plan views illustrating shapes of a sensing metal according to embodiments of the disclosure.

FIG. 6 illustrates a drilling process of a display device according to an embodiment of the disclosure.

FIG. 7 is a cross-sectional view illustrating a detailed structure of a display device according to an embodiment of the disclosure.

FIGS. 8A and 8B are cross-sectional views illustrating a comparison of a display device according to an embodiment of the disclosure and a display device according to a comparative example, respectively.

### DETAILED DESCRIPTION

Reference will now be made in detail to embodiments of the disclosure, examples of which are illustrated in the accompanying drawings. Wherever possible, the same reference numbers will be used throughout the drawings to refer to the same or like parts. Detailed descriptions of known arts will be omitted if such may mislead the embodiments of the disclosure. In describing various embodiments, the same components may be described in a first embodiment, and a description thereof may be omitted in other embodiments.

The terms “first,” “second,” etc. may be used to describe various components, but the components are not limited by such terms. The terms are used only for the purpose of distinguishing one component from other components.

A display device according to embodiments of the disclosure may be implemented based on a display device, such as a liquid crystal display (LCD), a field emission display (FED), a plasma display panel (PDP), an organic light emitting diode (OLED) display, an electrophoresis display, and a quantum dot display (QDD). In the following description, embodiments of the disclosure will be described using a liquid crystal display as an example of the display device. Other display devices may be used. The display device according to embodiments of the disclosure may be implemented as any type liquid crystal display including a transmissive liquid crystal display, a transflective liquid crystal display, a reflective liquid crystal display, etc.

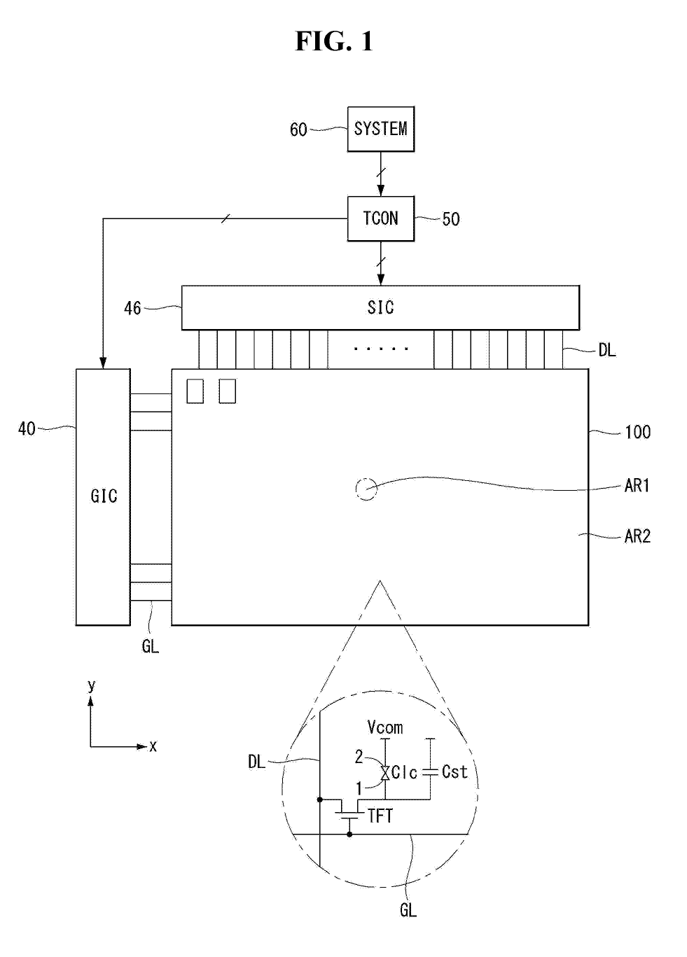

FIG. 1 is a schematic block diagram of a display device according to an embodiment of the disclosure.

Referring to FIG. 1, a display device according to an embodiment of the disclosure includes a display panel 100, a driver integrated circuit (IC), a timing controller (or referred to as “TCON”) 50, and the like.

The display panel 100 includes an active area and a bezel area outside the active area. The active area is a portion on which an input image is displayed, and includes a plurality of pixels defined by a crossing structure of gate lines GL and data lines DL. The bezel area includes a plurality of driving elements for applying driving signals to the active area.

The display panel 100 may be divided into a first area AR1 and a second area AR2 outside the first area AR1. As shown in FIG. 1, the second area AR2 may surround the first area AR1. The first area AR1 is an area where image information is not displayed, and performs an auxiliary function of the display device. The first area AR1 may be disposed in at least one of the active area and the bezel area.

The data lines DL are formed along a first direction (for example, a y-axis direction). A data voltage is applied to the data lines DL. The gate lines GL are formed along a second direction (for example, an x-axis direction) intersecting the first direction. Gate pulses are applied to the gate lines GL.

Thin film transistors (TFTs) are formed at intersections of the data lines DL and the gate lines GL. The term “intersect” is used herein to mean that one element crosses over or overlaps another element, and does not necessarily mean that the two elements contact each other. For example, the data lines DL and the gate lines GL may intersect each other, but may be physically separated from one another, for example, by one or more layers or elements provided therebetween. The TFT supplies the data voltage from the data line DL to a pixel electrode 1 of a liquid crystal cell Clc in response to the gate pulse from the gate line GL. Each liquid crystal cell Clc is driven by a voltage difference between the pixel electrode 1 charged with the data voltage through the TFT and a common electrode 2 supplied with a common voltage Vcom. A storage capacitor Cst is connected to the liquid crystal cell Clc and holds a voltage of the liquid crystal cell Clc during one frame period.

The driver IC is a driving circuit of the display panel 100 including a source driver IC SIC (or denoted as “46”) and a gate driver IC GIC (or denoted as “40”). The source driver IC SIC and the gate driver IC GIC may be together mounted on a flexible circuit board, for example, a chip-on film (COF). An input terminal of the COF may be attached to a printed circuit board (PCB), and an output terminal of the COF may be attached to the display panel 100. In some embodiments, the gate driver IC GIC may be directly disposed in the bezel area of the display panel 100 in a GIP (gate-driver in panel) circuit manner.

The source driver IC SIC samples and latches digital video data of an input image under the control of the timing controller 50 and converts the latched digital video data into parallel data. The source driver IC SIC converts the digital video data into analog gamma compensation voltages using a digital-to-analog converter (DAC) under the control of the timing controller 50 and generates data voltages. The source driver IC SIC then supplies the data voltages to the data lines DL. The gate driver IC GIC sequentially supplies gate pulses (or referred to as “scan pulses”) synchronized with the data voltages to the gate lines GL under the control of the timing controller 50.

The timing controller 50 receives digital video data of an input image from a host system 60 and transmits the digital video data to the source driver IC SIC. The timing controller 50 receives timing signals, such as a vertical sync signal Vsync, a horizontal sync signal Hsync, a data enable signal DE, and a main clock CLK, from the host system 60. The timing signals are synchronized with the digital video data of the input image. The timing controller 50 generates a source timing control signal for controlling operation timing of the source driver IC SIC and a gate timing control signal for controlling operation timing of the gate driver IC GIC using the timing signals Vsync, Hsync, DE, and CLK.

The host system 60 may be one of a television system, a set-top box, a navigation system, a DVD player, a Blu-ray player, a personal computer (PC), a home theater system, a phone system, and other systems that include or operate in conjunction with a display. The host system 60 converts digital video data of an input image into data of a format suitable for the display panel 100. The host system 60 transmits the digital video data of the input image and the timing signals Vsync, Hsync, DE, and CLK to the timing controller 50.

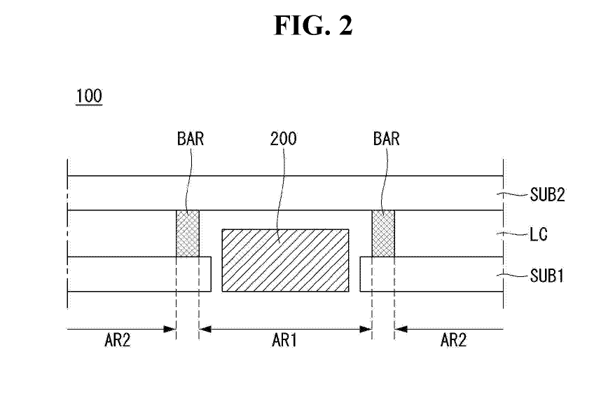

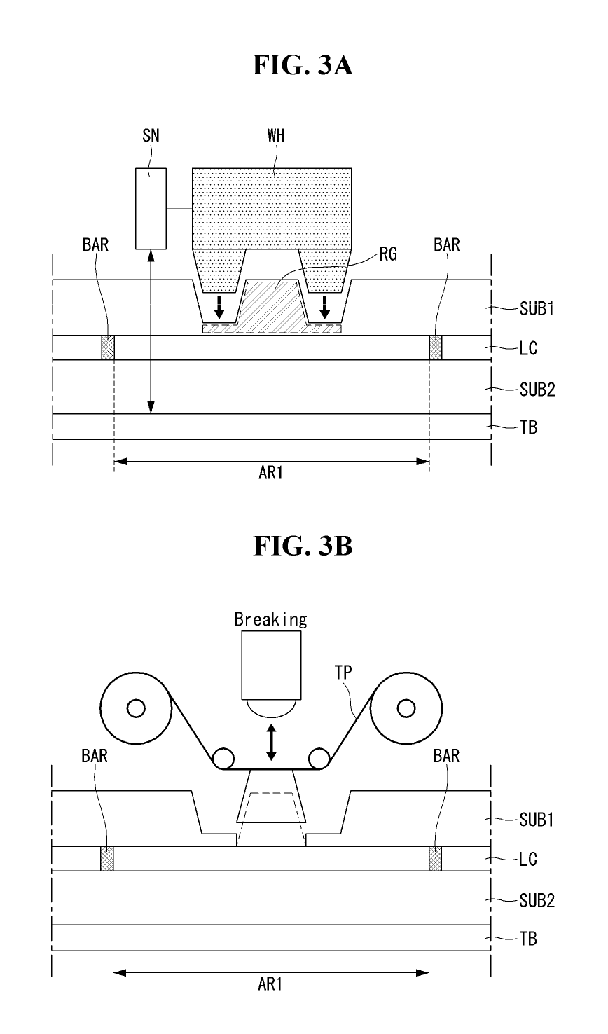

FIG. 2 is a cross-sectional view illustrating a schematic structure of a display device and FIGS. 3A and 3B are cross-sectional views illustrating a manufacturing process of a display device according to an embodiment of the disclosure.

Referring to FIG. 2, the display panel 100 includes a first substrate SUB1, a second substrate SUB2, and a liquid crystal layer LC. The first substrate SUB1 and the second substrate SUB2 may be formed of glass material. The first substrate SUB1 may be a thin film transistor array substrate on which thin film transistors are formed. The second substrate SUB2 may be a color filter array substrate on which color filters are formed.

The display panel 100 includes the first area AR1 and the second area AR2. The first area AR1 and the second area AR2 may be separated from each other by a barrier BAR. That is, as shown in FIG. 2, the first area AR1 may extend between an inner perimeter surface of the barrier BAR, and the second area AR2 may be positioned outside of an outer perimeter surface of the barrier BAR. The first substrate SUB1 is partially removed in the first area AR1. That is, a portion of the first substrate SUB1 is removed within the first area AR1, which forms an opening through the first substrate SUB1 that is located within the first area AR1. Therefore, the first area AR1 of the display panel 100 has an inner space that is partially opened to the outside.

An optical module 200 is introduced into the inner space provided in the first area AR1. For example, the optical module 200 may be introduced through the opening that extends through the first substrate SUB1 in the first area AR1. The optical module 200 therefore is not configured by a simple stack structure in which an optical module is stacked on the outside of the display panel 100, but instead at least a portion of the optical module 200 is introduced into the inside of the display panel 100 itself. Thus, the display device can implement a slim design through a reduction in an entire thickness of the display device, since the optical module 200 may be incorporated into an opening in the first area AR1 without increasing the thickness of the display panel. In some embodiments, the optical module 200 may be completely accommodated in the inner space of the display panel 100 and may not protrude to the outside of the display panel 100. Alternatively, in some embodiments, only at least a portion of the optical module 200 may be accommodated in the inner space of the display panel 100.

Referring to FIGS. 3A and 3B, a mechanical process for removing a portion of the first substrate SUB1 is performed in order to form the inner space inside the display panel 100. For example, a drilling process using a mechanical wheel WH may be performed.

More specifically, the mechanical wheel WH is prepared in the first area AR1 of the display panel 100 to process the display panel 100 provided on a table TB. Thereafter, as shown in FIG. 3A, the first substrate SUB1 in the first region AR1 is drilled through the drilling process using the mechanical wheel WH. The mechanical wheel WH may have a protruding portion that protrudes downwardly about the periphery of the mechanical wheel WH, and a recessed portion is surrounded by the protruding portion, as shown in FIG. 3A. The protruding portion of the mechanical wheel WH acts as a drill bit to drill out part of the first substrate SUB1 in the first region AR1. After drilling, a portion of the first substrate SUB1 corresponding to the recessed portion of the mechanical wheel WH remains. The remaining portion may be, for example, a portion of remaining glass RG in embodiments in which the first substrate SUB1 is a glass substrate. However, embodiments provided herein are not limited thereto, and in some embodiments, the first substrate SUB1 may be formed of other materials, including plastics or the like, and in such cases, the remaining portion may be a material other than glass. As shown in FIG. 3B, the remaining portion of the first substrate SUB1, e.g., a remaining glass RG remaining in the first area AR1 after the drilling process, is attached to a tape TP and is broken, and then is removed all at once. Accordingly, the inner space can be provided in the first area AR1 of the display panel 100 through a series of processes illustrated in FIGS. 3A and 3B.

As described above, the display device according to some embodiments of the disclosure utilizes the drilling process to provide an inner space in a portion of the display panel 100. In such embodiments, the drilling process should be precisely controlled. More specifically, the first substrate SUB1 may be formed using a material like glass. However, the first substrate SUB1 formed of the glass material may not have a uniform thickness and may have a thickness variation depending on a position. For example, a thickness variation of a glass substrate used for the first substrate SUB1 depending on a position of the glass substrate may be in a range of 0.25±0.05 mm. When the drilling process is performed without considering the thickness variation, the generation of burrs may increase. This may lead to a significant reduction in reliability and stability of the product. Further, when the drilling process is performed without considering the thickness variation, the remaining glass RG may not be completely removed and may partially remain because there occurs a thickness variation in the remaining glass RG after the drilling process. Therefore, as will be discussed in further detail below, in some embodiments the present disclosure provides a configuration and a method to measure a thickness variation of the first substrate SUB1 depending on a position and perform the drilling process based on the measured thickness variation.

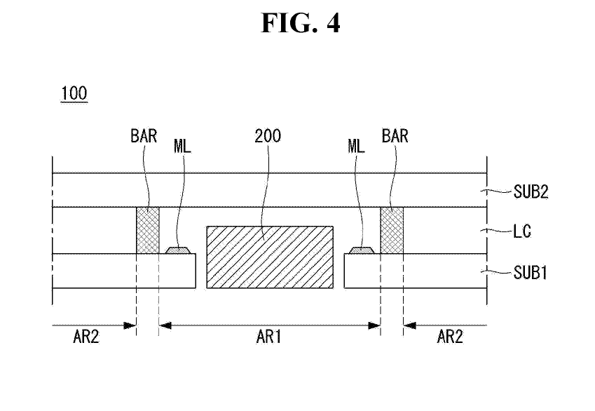

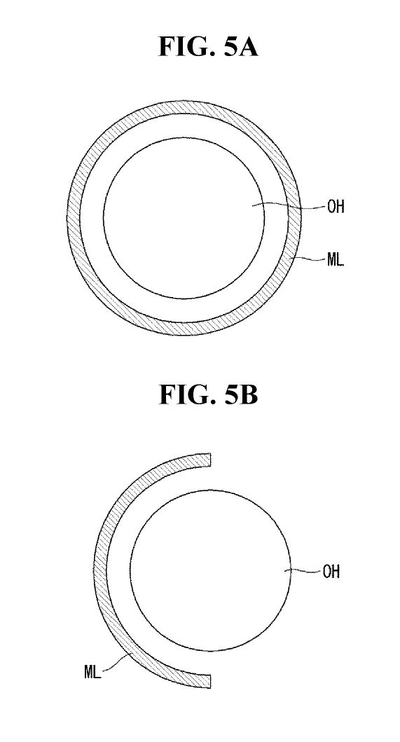

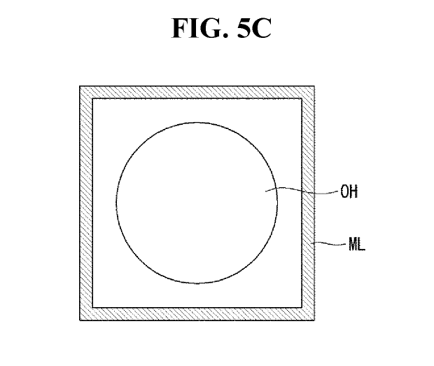

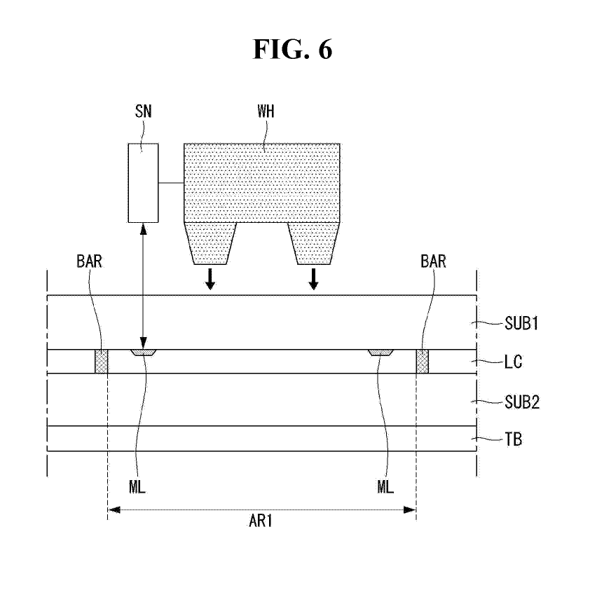

FIG. 4 is a cross-sectional view illustrating a schematic structure of a display device according to an embodiment of the disclosure. FIGS. 5A, 5B, and 5C are plan views illustrating a shape of a sensing metal according to an embodiment of the disclosure. FIG. 6 illustrates a drilling process of a display device according to an embodiment of the disclosure.

Referring to FIG. 4, a display device according to an embodiment of the disclosure includes a display panel 100 and an optical module 200. The display panel 100 includes a first substrate SUB1, a second substrate SUB2, and a liquid crystal layer LC. The first substrate SUB1 and the second substrate SUB2 may be formed of glass material, although embodiments of the present disclosure are not limited thereto. The first substrate SUB1 may be a thin film transistor array substrate on which thin film transistors are formed. The second substrate SUB2 may be a color filter array substrate on which color filters are formed. When the display panel is configured in a COT (color filter on TFT) structure, the color filters may be formed on the first substrate SUB1. The liquid crystal layer LC is disposed between the first substrate SUB1 and the second substrate SUB2. The liquid crystal layer LC may be implemented in various liquid crystal modes including a twisted nematic (TN) mode, a vertical alignment (VA) mode, an in-plane switching (IPS) mode, a fringe field switching (FFS) mode, etc.

The display panel 100 includes a first area AR1 and a second area AR2. The first area AR1 and the second area AR2 may be separated from each other by a barrier BAR. The barrier BAR may be formed of a sealing material such as a sealant. The barrier BAR can function to seal the liquid crystal layer LC, namely, to prevent liquid crystals from leaking to the outside. The barrier BAR can function to prevent foreign matter from entering the inside of the display panel 100, for example, into the liquid crystal layer LC during a process for forming an inner space in the first area AR1. In addition, the barrier BAR can function to keep a cell gap constant against an external pressure provided during the process for forming the inner space. That is, the barrier BAR can maintain a separation distance between the first and second substrates SUB1, SUB2 even while external pressures are applied, for example, during the process for forming the inner space through the first substrate SUB1.

The first substrate SUB1 in the first area AR1 is partially removed. That is, a portion of the first substrate SUB1 is removed within the first area AR1, which forms an opening through the first substrate SUB1 that is located within the first area AR1. Therefore, the first area AR1 of the display panel 100 has an inner space that is partially opened to the outside.

An optical module 200 is introduced into the inner space provided in the first area AR1. The optical module 200 is not configured by a simple stack structure in which an optical module is stacked on the outside of the display panel 100, but instead at least a portion of the optical module 200 is introduced into the inside of the display panel 100. Thus, the display device can implement a slim design through a reduction in an entire thickness of the display device, since the optical module 200 may be incorporated into the opening in the first area AR1 without increasing the thickness of the display panel. In some embodiments, the optical module 200 may be completely accommodated in the inner space of the display panel 100 and may not protrude to the outside of the display panel 100. Alternatively, in some embodiments, only at least a portion of the optical module 200 may be accommodated in the inner space of the display panel 100.

The optical module 200 may be at least one of a camera and an optical sensor such as an illuminance sensor. The optical module 200 is accommodated in the inner space provided inside the display panel 100 and may be positioned on a back surface of the second substrate SUB2, and the optical module 200 can therefore be prevented from interfering with other structures during the process and/or during use of the product. The optical module 200 may be directly attached to the back surface of the second substrate SUB2.

Because the second substrate SUB2 is formed of a transparent material such as glass, the first region AR1 of the display panel 100 corresponds to a transmission region capable of transmitting light. This means that a path of light in the first area AR1 is not disturbed by the second substrate SUB2. Hence, the optical module 200 positioned on the back surface of the second substrate SUB2 can perform its function.

A backlight unit (not shown) may be disposed in the rear of the display panel 100 at a position corresponding to the second area AR2. The display device according to one or more embodiments of the disclosure displays an image by controlling an electric field applied to the liquid crystal layer LC and modulating light provided by the backlight unit.

The backlight unit may be implemented as at least one of a direct type backlight unit and an edge type backlight unit. The edge type backlight unit is configured such that a light source is disposed opposite a side of a light guide plate, and a plurality of optical sheets is disposed between the display panel 100 and the light guide plate. The direct type backlight unit is configured such that a plurality of optical sheets and a diffusion plate are stacked below the display panel 100, and a plurality of light sources is disposed below the diffusion plate.

A sensing metal ML is disposed on the first substrate SUB1. The sensing metal ML is configured to accurately measure a thickness variation of the first substrate SUB1, and the sensing metal ML may be directly disposed on the first substrate SUB1. For example, the sensing metal ML may be disposed on a surface of the first substrate SUB1 that faces the second substrate SUB2, as shown in FIG. 4.

The sensing metal ML may be disposed in the first area AR1. More particularly, the sensing metal ML may be disposed in the first area AR1 and sufficiently spaced from the elements disposed in the second area AR2 in which an input image is displayed, in order to prevent an unnecessary signal interference between the sensing metal ML and signal electrodes, signal lines, etc. disposed in the second area AR2. As shown in FIG. 4, the sensing metal ML may be spaced apart from the barrier BAR.

The sensing metal ML may be formed of a material capable of being sensed by a sensor. Namely, the sensing metal ML may be formed of a metal material that is easily sensed by a distance measuring sensor SN. This will be described in further detail later. For example, the sensing metal ML may be formed as a single layer or a multilayer including at least one of copper (Cu), molybdenum (Mo), aluminum (Al), chrome (Cr), gold (Au), titanium (Ti), nickel (Ni), neodymium (Nd), tantalum (Ta), tungsten (W), or an alloy thereof.

The sensing metal ML is spaced from an open hole OH by a predetermined distance, as shown in FIGS. 5A, 5B, and 5C. The open hole OH is a hole formed by penetrating the first substrate SUB1 through the above-described drilling process. That is, the open hole OH corresponds to the opening formed through the first substrate SUB1 in the first area AR1, as shown in FIG. 4. In order to accurately measure a thickness of a portion of the first substrate SUB1 to be processed, the predetermined distance may be selected to be as short as possible in the process. That is, the sensing metal ML may be positioned at a position that is very close to the position where the open hole OH will be formed; however, it may be desirable to have some amount of distance between an edge of the sensing metal ML and the position where the open hole OH will be formed, so that the sensing metal ML is not damaged during the process of forming the open hole OH. The predetermined distance may be appropriately selected in consideration of a formation position of the open hole OH, a position of the barrier BAR, a position of the distance measuring sensor SN, and the like.

Referring to FIG. 5A, the sensing metal ML may have a closed curve shape when viewed on the plane, i.e., in a top plan view. When the sensing metal ML of the closed curve shape surrounds the entire circumference of the open hole OH, the entire thickness of the first substrate SUB1 can be measured in a region where the open hole OH is to be formed. Therefore, the drilling process can be performed more accurately based on sensed distance information. However, embodiments are not limited thereto. For example, as shown in FIG. 5B, the sensing metal ML may be selectively formed in an open curve shape at a predetermined position of the open hole OH. That is, the sensing metal ML may have a semi-circular shape in top plan view, with the sensing metal ML partially surrounding, and spaced apart at a predetermined distance from, the open hole OH.

FIGS. 5A, 5B, and 5C illustrates that the open hole OH has a substantially circular planar shape, by way of example. However, embodiments are not limited thereto. For example, the open hole OH may have any shape capable of smoothly accommodating the optical module 200. FIG. 5A illustrates that the planar shape of the sensing metal ML has a substantially circular ring shape, by way of example. However, embodiments are not limited thereto. For example, the planar shape of the sensing metal ML may have various planar shapes including a hollow circular shape, a polygonal shape, etc. In addition, the planar shape of the sensing metal ML may be different from the planar shape of the open hole OH. For example, as shown in FIG. 5C, the open hole OH may have a substantially circular shape in top plan view, while the sensing metal ML may have a square shape in top plan view. However, because the sensing metal ML is disposed adjacent to the open hole OH in order to accurately measure the thickness variation of the first substrate SUB1 corresponding to the formation position of the open hole OH, the planar shape of the sensing metal ML may be substantially the same as the planar shape of the open hole OH.

Referring to FIG. 6, a mechanical processing for removing a portion of the first substrate SUB1 is performed in order to provide the inner space inside the display panel 100. For example, a drilling process using a mechanical wheel WH may be performed.

More specifically, the mechanical wheel WH is prepared in the first area AR1 of the display panel 100 to process the display panel 100 provided on a table TB. Thereafter, the first substrate SUB1 of the first region AR1 is drilled through the drilling process using the mechanical wheel WH.

The distance measuring sensor SN may be used to accurately perform the drilling process so that the first substrate SUB1 is drilled up to a desired depth. Namely, the distance measuring sensor SN may sense a position of the sensing metal ML and a distance from the sensing metal ML. Hence, embodiments of the disclosure can sense a thickness variation (depending on a position) of the first substrate SUB1 at a position corresponding to the open hole OH and can accurately determine a drilling depth (i.e., a drilling depth of the mechanical wheel WH) depending on a position. That is, the drilling depth may be determined based on the sensed distance between the distance measuring sensor SN and the sensing metal ML, and the mechanical wheel WH may be controlled to stop drilling when a desired drilling depth has been reached, for example as determined based on the distance between the distance measuring sensor SN and the sensing metal ML. If necessary or desired, embodiments of the disclosure may measure a distance between the first substrate SUB1 and the table TB, on which the display panel 100 is provided, using the distance measuring sensor SN and may perform the drilling process up to a desired position in further consideration of the entire thickness of the display panel 100. Embodiments of the disclosure perform the drilling process in consideration of the thickness variation (depending on the position) of the first substrate SUB1, and thus can reduce the generation of burr. As a result, embodiments of the disclosure can provide the display device in which the reliability and the stability of the product are secured.

The distance measuring sensor SN may be any sensor capable of sensing the sensing metal ML, and more particularly, of sensing a distance to the sensing metal ML. For example, in some embodiments, the distance measuring sensor SN may be a capacitive sensor, a capacitive displacement sensor, or the like. The sensing metal ML may be any metal capable of being sensed by the distance measuring sensor SN. In some embodiments, the sensing metal ML may be provided for the sole purpose of being sensed by the distance measuring sensor SN in order to accurately perform the drilling process as described herein. Accordingly, in some embodiments, the sensing metal ML may be electrically isolated from other metal features or components in the display device.

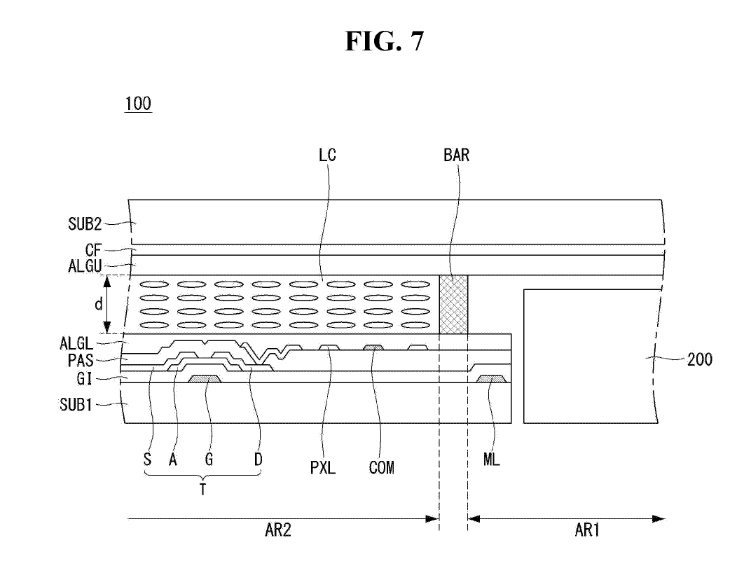

FIG. 7 is a cross-sectional view illustrating a detailed structure of a display device according to an embodiment of the disclosure.

A display panel 100 includes a first area AR1 and a second area AR2. The first area AR1 and the second area AR2 may be separated from one another by a barrier BAR.

The display panel 100 includes a first substrate SUB1 and a second substrate SUB2 that are positioned opposite each other. An optical module 200 is disposed in an inner space provided in the first area AR1 in a rear direction of the second substrate SUB2. That is, the inner space may correspond to an opening formed through the first substrate SUB1, and the first substrate SUB1 may be positioned below a rear surface of the second substrate SUB2, as shown in FIG. 7. In the second region AR2, the first substrate SUB1 and the second substrate SUB2 are attached to each other while maintaining a predetermined distance “d” therebetween with a liquid crystal layer LC interposed therebetween. A lower polarizing plate and an upper polarizing plate may be respectively disposed on an outer surface of the first substrate SUB1 and an outer surface of the second substrate SUB2. The upper polarizing plate may have a light transmission axis perpendicular to the lower polarizing plate.

In the second area AR2, thin film transistors (TFTs) T, pixel electrodes PXL, and a common electrode COM are disposed on the first substrate SUB1. Each TFT T includes a gate electrode G, a semiconductor layer A, a source electrode S, and a drain electrode D. The gate electrode G is disposed on the first substrate SUB1. A gate insulating layer GI is disposed on the gate electrode G and covers the gate electrode G. The semiconductor layer A is disposed on the gate insulating layer GI and overlaps the gate electrode G. A portion of the semiconductor layer A overlapping the gate electrode G may be defined as a channel region. The source electrode S and the drain electrode D are disposed on the semiconductor layer A and are positioned opposite each other to be spaced from each other by a predetermined distance. The source electrode S is in contact with one side of the semiconductor layer A, and the drain electrode D is in contact with the other side of the semiconductor layer A. A structure of the TFT T applied to embodiments of the disclosure is not limited to the structure illustrated in FIG. 7. For example, embodiments of the disclosure may include various structures including a top gate structure, a bottom gate structure, a double gate structure, etc. Further, the TFTs T according to embodiments of the disclosure may be implemented as an amorphous silicon (a-Si) TFT, a low-temperature polycrystalline silicon (LTPS) TFT, or an oxide TFT.

An insulating layer PAS is formed on the gate insulating layer GI, the semiconductor layer A, the source electrode S, and the drain electrode D. The insulating layer PAS may include one or more insulating layers. For example, the insulating layer PAS may include a first insulating layer and a second insulating layer. The first insulating layer may include an inorganic insulating material, and the second insulating layer may include an organic insulating material. The second insulating layer may include an organic insulating material and serve as a planarization layer.

The pixel electrode PXL and the common electrode COM, each of which may include a conductive material, are formed on the insulating layer PAS. Positions and shapes of the pixel electrode PXL and the common electrode COM may be suitably selected depending on to the design environment and purpose.

For example, the pixel electrode PXL and the common electrode COM may be formed on the same layer using the same material. The pixel electrode PXL and the common electrode COM are spaced from each other by a predetermined distance. During operation of the display panel 100, the pixel electrode PXL and the common electrode COM form a horizontal electric field, and liquid crystals provided on the pixel electrode PXL and the common electrode COM are driven by the horizontal electric field. As another example, the pixel electrode PXL and the common electrode COM may be provided on different layers with a third insulating layer interposed therebetween. Namely, the pixel electrode PXL and the third insulating layer covering the pixel electrode PXL may be sequentially formed on the insulating layer PAS, and the common electrode COM may be formed on the third insulating layer and may form a horizontal electric field together with the pixel electrode PXL. Alternatively, the common electrode COM and the third insulating layer covering the common electrode COM may be sequentially formed on the insulating layer PAS. The pixel electrode PXL may be formed on the third insulating layer and may form a horizontal electric field together with the common electrode COM. As another example, the common electrode COM may be formed on the second substrate SUB2 and may operably form a vertical electric field together with the pixel electrode PXL formed on the first substrate SUB1.

The pixel electrode PXL is in contact with a portion of the drain electrode D exposed through a pixel contact hole penetrating the insulating layer PAS. Thus, the pixel electrode PXL is electrically connected to the drain electrode D. A lower alignment layer ALGL is formed on the first substrate SUB1 on which the pixel electrode PXL and the common electrode COM are formed.

Color filters CF are formed on the second substrate SUB2. The color filters CF may be configured to have R/G/B arrangement or R/G/B/W arrangement in accordance with the arrangement of pixels. A black matrix capable of partitioning an R color filter, a G color filter, and a B color filter may be further provided on the second substrate SUB2. An upper alignment film ALGU is formed on the second substrate SUB2 on which the color filters CF are formed.

In the first area AR1, a sensing metal ML is formed on the first substrate SUB1. The sensing metal ML may be formed together when the gate electrode G is formed. Namely, the sensing metal ML may be formed on the same layer using the same material as the gate electrode G through the same process. Accordingly, in some embodiments of the disclosure, an additional process for forming the sensing metal ML is not required because the sensing metal ML can be formed together when the gate electrode G is formed. Thus, embodiments of the disclosure can reduce the manufacturing cost, manufacturing time, and the like.

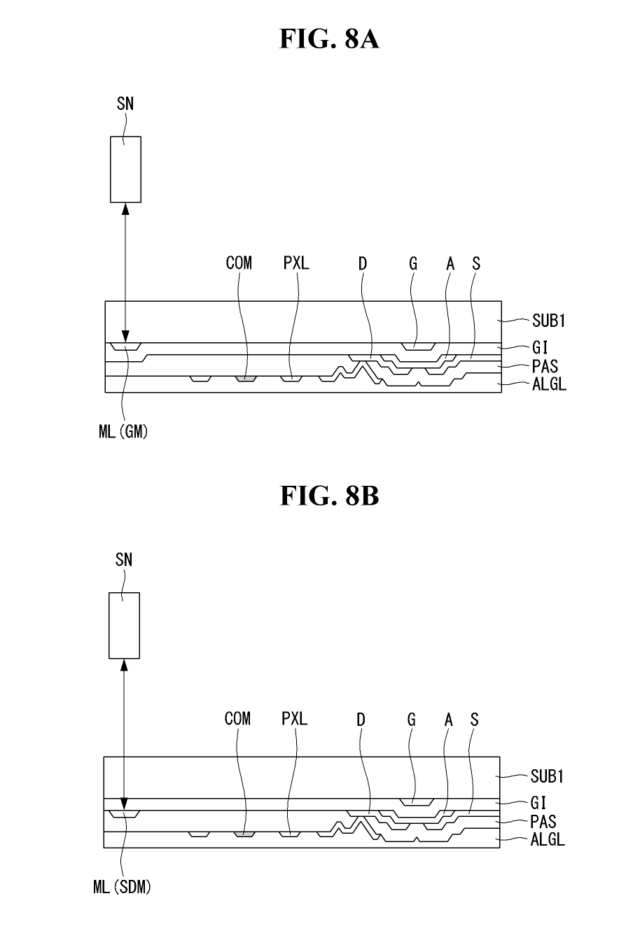

FIGS. 8A and 8B are cross-sectional views illustrating a comparison of a display device according to an embodiment of the disclosure and a display device according to a comparative example, respectively.

Referring to FIG. 8A, which illustrates a display device according to a preferred embodiment of the disclosure, a sensing metal ML can be formed on the same layer using the same material GM as a gate electrode G directly positioned on a first substrate SUB1 through the same process. In this instance, a thickness of the first substrate SUB1 corresponding to a processing position can be accurately measured without considering other factors (or conditions).

Referring to FIG. 8B, which illustrates a display device according to a comparative example, a sensing metal ML may be disposed on a first substrate SUB1 with a gate insulating layer GI interposed therebetween. For example, the sensing metal ML may be formed on the same layer SDM using the same material as a source electrode S and a drain electrode D through the same process.

When a specific layer is disposed between the sensing metal ML and the first substrate SUB1 as described above, a thickness of the specific layer (e.g., the gate insulating layer GI) needs to be considered to measure a thickness variation of the first substrate SUB1 corresponding to a processing position. Because a thickness variation of the gate insulating layer GI depending on a position of the gate insulating layer GI may be in a range of 6000±1000 Å, it may be difficult to accurately measure the thickness of the of the first substrate SUB1 using the sensing metal ML on the gate insulating layer GI.

Thus, the sensing metal ML according to embodiments of the disclosure can be directly positioned on the first substrate SUB1.

The embodiments of the disclosure can provide the display device having the slim design while securing the reliability and the stability of the product. In particular, the embodiments of the disclosure can reduce process defects of the display device while providing the display device having the slim design.

Although embodiments have been described with reference to a number of illustrative embodiments thereof, it should be understood that numerous other modifications and embodiments can be devised by those skilled in the art that will fall within the scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a display panel including:
a first substrate having a hole that extends through at least a portion of the first substrate,
a second substrate positioned opposite to the first substrate, and
a sensing metal on a surface of the first substrate that faces the second substrate, the sensing metal positioned adjacent to the hole in the first substrate; and
an optical module at least partially located within the hole of the first substrate.

2. The display device of claim 1, wherein the sensing metal is directly disposed on the first substrate.

3. The display device of claim 1, wherein the sensing metal is spaced apart from the first substrate by an insulating layer.

4. The display device of claim 1, wherein the sensing metal has a planar shape of a closed curve.

5. The display device of claim 1, further comprising a thin film transistor on the first substrate, the thin film transistor including:
a gate electrode directly disposed on the first substrate;
a gate insulating layer on the gate electrode;
a semiconductor layer disposed on the gate insulating layer, the semiconductor layer at least partially overlapping the gate electrode; and
a source electrode and a drain electrode disposed on the semiconductor layer and respectively contacting opposite sides of the semiconductor layer,
wherein the sensing metal is formed on a same layer and of a same material as the gate electrode.

6. The display device of claim 1, wherein the display panel includes:
a first area in which the hole is positioned;
a second area disposed outside the first area, the second area operable to display an input image; and
a barrier disposed between the first substrate and the second substrate and partitioning the first area and the second area.

7. The display device of claim 6, wherein the sensing metal is disposed in the first area.

8. The display device of claim 7, wherein the sensing metal is spaced apart from the barrier.

9. The display device of claim 6, further comprising a liquid crystal layer between the first substrate and the second substrate in the second area.

10. The display device of claim 1, wherein the hole and the sensing metal have a same planar shape.

11. The display device of claim 10, wherein the planar shape of the hole and the sensing metal is a circular or semi-circular shape.

12. The display device of claim 1, wherein the optical module includes at least one of a camera and an optical sensor.

13. A method, comprising:
positioning a mechanical wheel over a first substrate of a display panel, the display panel including a second substrate positioned opposite to the first substrate, and a sensing metal on a surface of the first substrate that faces the second substrate;
sensing a distance between a distance sensor and the sensing metal; and
drilling a region of the first substrate, by the mechanical wheel, to a selected depth while sensing the distance between the distance sensor and the sensing metal.

14. The method of claim 13, further comprising:
determining, based on the sensed distance between the distance sensor and the sensing metal, that the first substrate has been drilled to the selected depth.

15. The method of claim 13, further comprising:
removing a portion of the first substrate to form a hole through the first substrate, the hole corresponding to the drilled region of the first substrate.

16. The method of claim 15, further comprising:
positioning at least one of a camera and an optical sensor in the hole.
